(19) United States
(12) Patent Application Publication
(10) Pub. No.: US 2021/0320054 A1
(43) Pub. Date: Oct. 14, 2021

(54) HEATSINK FOR THERMAL RESPONSE CONTROL FOR INTEGRATED CIRCUITS

(71) Applicant: SEMICONDUCTOR COMPONENTS INDUSTRIES, LLC, Phoenix, AZ (US)

(72) Inventors: Hiroshi INOGUCHI, Tatebayashi (JP); Takashi NAGASHIMA, Sano-shi (JP); Roger Paul STOUT, Chandler, AZ (US); Namrata KANTH, Tempe, AZ (US)

(73) Assignee: SEMICONDUCTOR COMPONENTS INDUSTRIES, LLC, Phoenix, AZ (US)

(21) Appl. No.: 16/846,778

(22) Filed: Apr. 13, 2020

(51) Int. Cl. H01L 23/495; H01L 23/367; H01L 23/498; H01L 23/373; H01L 21/48; H01L 21/56

(52) U.S. Cl. CPC H01L 23/49568; H01L 23/367; H01L 21/565; H01L 23/3736; H01L 21/4842; H01L 23/49861

(57) ABSTRACT

A semiconductor device package includes a leadframe, and a heatsink bonded to the leadframe. A semiconductor device may be mounted using the leadframe and positioned such that heat generated by the semiconductor device is conducted by the heatsink, with molding that encapsulates the leadframe, the heatsink, and the semiconductor device.

### TECHNICAL FIELD

This description relates to semiconductor packaging techniques for thermal control.

### BACKGROUND

Semiconductor devices have a limited ability to withstand heat, so that excess heat from either external or internal sources may cause malfunction or damage. For example, external heat sources may be associated with an operational environment of an integrated circuit (IC) chip, such as an automotive environment. Excessive heat from internal sources may occur, for example, in the context of high power IC chips.

In many cases, excessive heat is transient, such as when a source of heat is short-lived. In such cases, IC chips may be configured for auto-turnoff in response to a thermal threshold being crossed, but may resume operations once the transient heat source has abated.

While turned off, an IC chip may be less susceptible to damage than when operating, and may avoid or minimize further increases in temperature associated with internal device operations. However, turning off semiconductor devices is undesirable from the perspective of achieving intended uses of such devices.

### SUMMARY

According to one general aspect, a semiconductor device package includes a leadframe, and a heatsink bonded to the leadframe. The semiconductor device package includes a semiconductor device mounted using the leadframe and positioned such that heat generated by the semiconductor device is conducted by the heatsink, and molding that encapsulates the leadframe, the heatsink, and the semiconductor device.

According to another general aspect, a semiconductor device package includes a leadframe having a substantially flat leadframe surface, and a heatsink having a substantially flat heatsink surface that is bonded to the substantially flat leadframe surface. The semiconductor device package includes a semiconductor device mounted using the leadframe and positioned such that heat generated by the semiconductor device is conducted by the heatsink.

According to another general aspect, a method of manufacturing a semiconductor device package includes bonding a heatsink onto a leadframe. The method further includes mounting a semiconductor device using the leadframe, and encapsulating the leadframe, the semiconductor device, and the heatsink within a molding.

The details of one or more implementations are set forth in the accompanying drawings and the description below. Other features will be apparent from the description and drawings, and from the claims.

### BRIEF DESCRIPTION OF THE DRAWINGS

FIG. 1 is a simplified cross section view of a heatsink for thermal response control within a semiconductor package.

FIG. 2 is a side angle view of an example implementation of the package of FIG. 1, with the heatsink mounted between a leadframe and a semiconductor device.

FIG. 3 is a cross section view of the example of FIG. 2.

FIG. 4 is a side angle view of an alternate implementation of the implementation of FIGS. 2 and 3.

FIG. 5 illustrates an example process for bonding a semiconductor device to a heatsink sheet to obtain the implementation of FIG. 2.

FIG. 6 illustrates a more detailed example process flow for executing the process of FIG. 5.

FIG. 7 illustrates further example processes for constructing the implementation of FIG. 2.

FIG. 8 is a side angle view of a second example implementation of the package of FIG. 1, with a heatsink mounted to an opposite side of a leadframe as a semiconductor device.

FIG. 9 is a cross section view of the example of FIG. 8.

FIG. 10 illustrates an example process for heatsink dicing to obtain a heatsink for use in the example of FIGS. 8 and 9.

FIG. 11 illustrates a process for welding a heatsink obtained from the process of FIG. 10 to a leadframe to obtain the example of FIGS. 8 and 9.

FIG. 12 is a side angle view of a third example implementation of the package of FIG. 1, with heatsinks mounted both between a semiconductor device and a leadframe, and to an opposite side of the leadframe.

FIG. 13 is a cross section view of the example of FIG. 12.

FIG. 14 is a flowchart illustrating an example process flow for manufacturing the example implementations of FIGS. 1-13.

FIG. 15 is a cross section view of an example implementation of the semiconductor package of FIG. 1, showing relative thicknesses of various portions thereof.

FIG. 16 illustrates graphs demonstrating a time until thermal shutdown of an example semiconductor device.

FIG. 17 is a graph illustrating a time required for different example implementations to reach a thermal shutdown temperature.

FIG. 18 illustrates graphs demonstrating a time until thermal release following the example thermal shutdowns of FIGS. 16 and 17.

FIG. 19A is a graph illustrating a time required for different example implementations to reach thermal release.

FIG. 19B illustrates a graph representing a maximum temperature reached for each implementation, and corresponding table.

FIG. 20 illustrates graphs demonstrating example configuration options for optimizing a transient thermal response of the semiconductor package of FIG. 1.

### DETAILED DESCRIPTION

Transient thermal response characteristics of semiconductor devices may be optimized and otherwise managed through the addition of an internally bonded heatsink(s) having dimensions and other characteristics selected during a design phase to obtain the desired thermal transient response during operation. Accordingly, a transient thermal response of semiconductor devices may be controlled so as to enable dissipation of heat energy for intermittent high power operation.

In particular, it is often preferable to enable a relatively large amount of time between a potential over-temperature event and an actual shutdown of an associated semiconductor device (referred to herein as a thermal shutdown, or TSD) that occurs at a pre-defined shutdown temperature. Increasing a time until TSD enables longer and more continuous use of the protected semiconductor device, and increases a chance that TSD may be avoided.

On the other hand, if TSD does occur, then it is generally desirable to resume operations of the semiconductor device as quickly as possible. Resumption of normal operations is referred to herein as thermal release, or TR. Such thermal release generally occurs once the semiconductor device has cooled below a thermal release temperature.

Accordingly, it may be desirable to balance the trade-offs between TSD and TR characteristics, which together contribute to a transient thermal response of a semiconductor device. For example, some designers, for some devices and associated applications, may prioritize delaying TSD, even at the expense of an increased time until thermal release. Other designers, conversely, may prefer to have a relatively larger thermal release time, even at the expense of a faster TSD.

Techniques described herein provide an ability to optimize transient thermal response characteristics in a low-cost, straightforward, configurable, and efficient manner, while maintaining an overall ease of manufacturing. Other than the steps required to add the described heatsinks, remaining manufacturing steps may remain the same, or substantially the same.

Further, a size of a semiconductor package housing the semiconductor device(s) and heatsinks may be maintained. In other words, it is not necessary to increase a package size in order to include the described heatsinks and obtain the desired transient response characteristics.

Still further, the described techniques enable an ease and flexibility of manufacture of associated components, such as leadframes. For example, a single leadframe configuration may be manufactured and used with many different heatsink configurations, to obtain different, desired transient thermal response characteristics.

In various implementations, heatsinks may be manufactured simply by dicing Cu alloy materials to a desired size. Resulting heatsinks may be bonded to leadframes using many available techniques, such as welding and soldering, e.g., using Ag paste. Multiple heatsinks, of the same or different dimensions, may be stacked to obtain larger heatsink thicknesses.

Heatsinks may be positioned at one or more of a plurality of positions on a leadframe relative to a semiconductor device being protected by the heatsink. For example, heatsinks may be placed on a first surface of a leadframe, and in between the leadframe and the semiconductor device. In other implementations, a heatsink may be placed on an opposing surface of the leadframe from the semiconductor device.

By including the heatsinks within a semiconductor device package, such as within a package molding, the overall semiconductor device package may be maintained at an existing size, and with an existing footprint. For example, in some implementations, the heatsink(s) may be completely enclosed and encapsulated within the package molding.

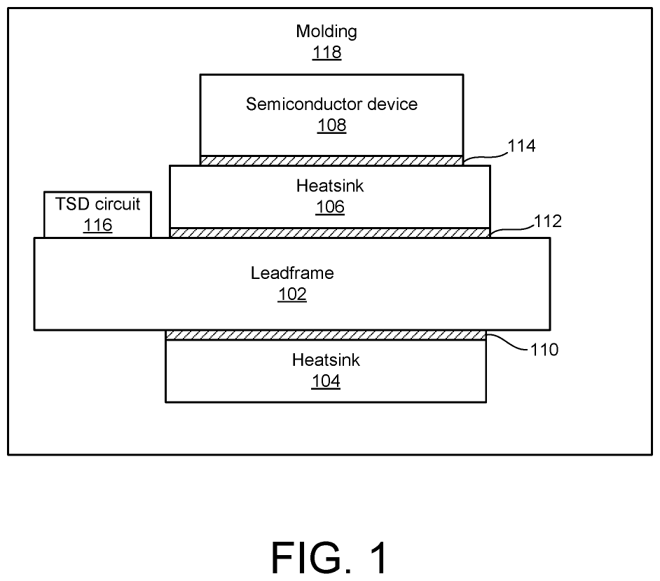

FIG. 1 is a simplified cross section view of a heatsink for thermal response control within a semiconductor package. In FIG. 1, a leadframe 102 is illustrated as having a heatsink 104 bonded to a first surface of the leadframe 102. In FIG. 1, a second heatsink 106 is bonded to a second, opposing surface of the leadframe, and a semiconductor device 108 is mounted on the heatsink 106.

In the example of FIG. 1, bonding of the heatsink 104 to the leadframe 102 is accomplished using bonding material 110, while the heatsink 106 is bonded using bonding material 112. The semiconductor device 114 is mounted on the heatsink 106 using bonding material 114. Thus, the semiconductor device 108 is mounted using the leadframe 102 (either directly or indirectly via the heatsink 106), while the heatsinks 104, 106 are each metallurgically bonded to the leadframe 102, and positioned to disperse heat generated by the semiconductor device 108.

Advantageously, the bonding materials 110, 112, 114 may represent one or more of many available and suitable types of bonding materials, and/or bonding techniques. For example, as described in more detail below, such bonding materials may include solder, such as solder paste, e.g., Ag paste. As also referenced below, other bonding techniques, such as ultrasonic or laser welding, also may be used.

In various implementations, the semiconductor device 108 may represent many different types and combinations of semiconductor devices. As illustrated below, multiple semiconductor devices may be included on (mounted to) the leadframe 102, with or without a heatsink such as the heatsink 106. In some examples, the semiconductor device 108 may represent power modules, which may use, e.g., one or more of an Insulated Gate Bipolar Transistor (IGBT) and/or a diode, such as a Fast Recovery Diode (FRD).

As referenced above, such high power devices may be susceptible to thermal shutdown events, as represented by TSD circuit 116. TSD circuit 116 represents any suitable approach for monitoring relevant temperatures and triggering subsequent thermal shutdowns of one or more devices, including the semiconductor device 116, and corresponding thermal releases. In the simplified example of FIG. 1, the TSD circuit 116 illustrates that relevant circuitry may be partially or completely included within an overall package molding 118, but in other implementations, the TSD 116 may be at least partially implemented outside of the molding 118.

The molding 118 represents any suitable package molding. For example, epoxy molding compound(s) (EMC) may be used.

In example implementations, the relevant surfaces of the leadframe 102 and the heatsinks 104, 106 are substantially flat. Accordingly, and because of the sizes of the heatsinks 104, 106, and the reliability of the bonding materials 110, 112 (or other bonding techniques), the heatsinks 104, 106 may be included in an efficient and reliable manner. The heatsinks 104, 106 may be of uniform thickness, and may be substantially rectangular in shape. An entirety of a substantially flat surface of the heatsink(s) 104, 106 may be bonded to the leadframe 102 using one of the bonding techniques described herein, and without requiring a separate or additional mechanical mounting of the heatsinks 104, 106 to the leadframe 102.

Further, encapsulation by the molding 118 may further ensure reliable connection and attachment of the heatsinks 104, 106. In general, encapsulation refers to, and includes, any enclosure or containment of one or more components of the package of FIG. 1 by surrounding portions of the molding 118. For example, one or more of the heatsinks 104, 106 may be completely encapsulated by the molding 118, so that no surface of the heatsink(s) 104, 106 is exposed outside of the molding 118.

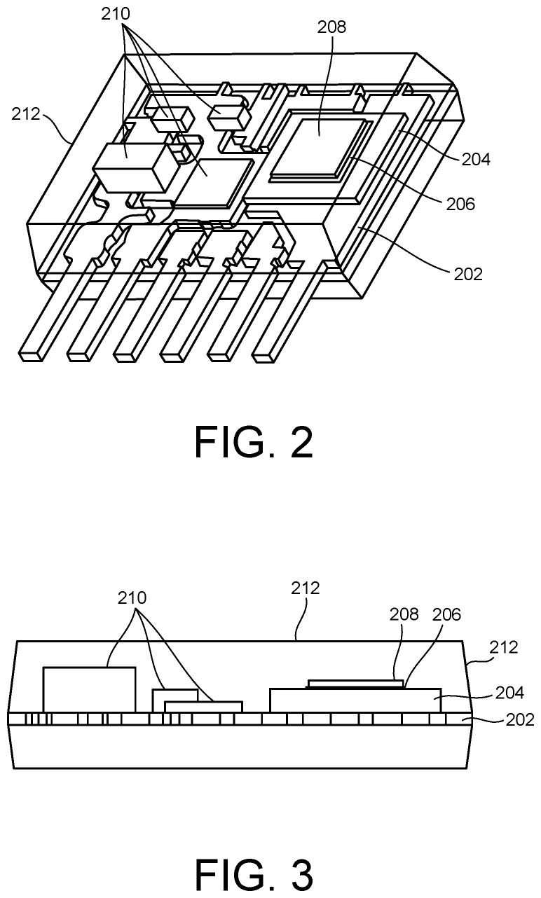

FIG. 2 is a side angle view of an example implementation of the package of FIG. 1, with the heatsink mounted between a leadframe and a semiconductor device. FIG. 3 is a cross section view of the example of FIG. 2.

In the example of FIGS. 2 and 3, a leadframe 202 is illustrated as being metallurgically bonded to a heatsink 204. A bonding material 206 further mounts a semiconductor device 208 to the heatsink 204.

Thus, FIGS. 2 and 3 represent an example embodiment of FIG. 1 in which the heatsink 106 is included, but not the heatsink 104. As also referenced above, multiple other semiconductor devices 210 may be included on the leadframe 202. A molding 212 is illustrated as completely encapsulating and enclosing the leadframe 202, heatsink 204, and the semiconductor devices 208, 210.

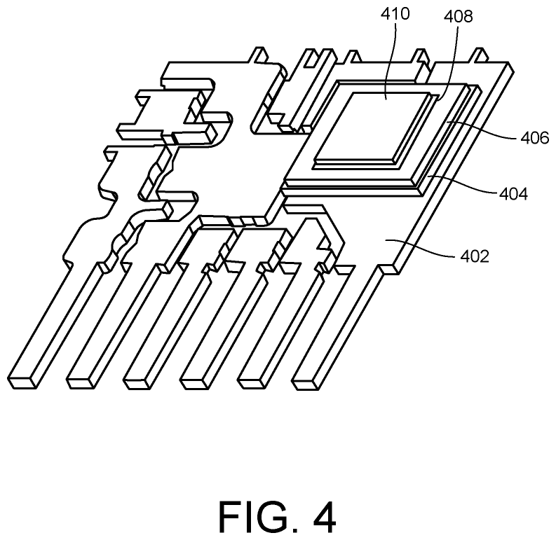

FIG. 4 is a side angle view of an alternate implementation of the implementation of FIGS. 2 and 3. As shown, a leadframe 402 may have a first heatsink 404 mounted thereon, with a second heatsink 406 mounted on the first heatsink 404. Then, suitable bonding material 408 may be used to mount a semiconductor device 410 to the heatsink 406.

In other words, the heatsink 406 may be said to be stacked on the heatsink 404. Such a stacked configuration may include two or more heatsinks of one or more thicknesses, in order to obtain a desired overall thickness of the stacked heatsinks. The stacked heatsinks 404, 406 may have the same or different length/width dimensions, as well. Such variations in overall heatsink dimensions enables a designer to choose a suitable overall dimension(s) for a desired thermal transient response.

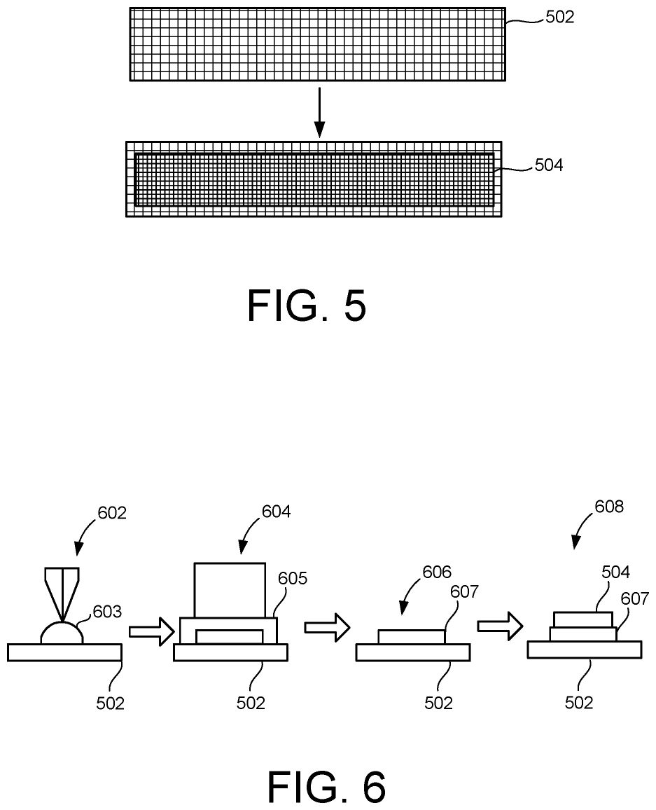

FIG. 5 illustrates an example process for bonding a semiconductor device to a heatsink sheet to obtain the implementation of FIG. 2. For example, a sheet 502 of suitable HS material, such as a suitable Cu alloy, may have a pattern defined for a plurality of heatsinks to be cut. As shown in the example, perpendicular lines may be used to define squares/rectangles that may be used as a heatsink(s) in the manners described herein. Then, in the example, a plurality of IGBT devices 504 may be bonded (e.g., using solder wire) to corresponding divisions of the sheet 502, to thereby form a plurality of heatsink/device stacks.

FIG. 6 illustrates a more detailed example process flow for executing the process of FIG. 5. As shown, solder 603 may be deposited (602), followed by shaping of the solder using a spunker 605. In this way, the shaped solder 607 is obtained (606), and IGBT 504 may be deposited (608).

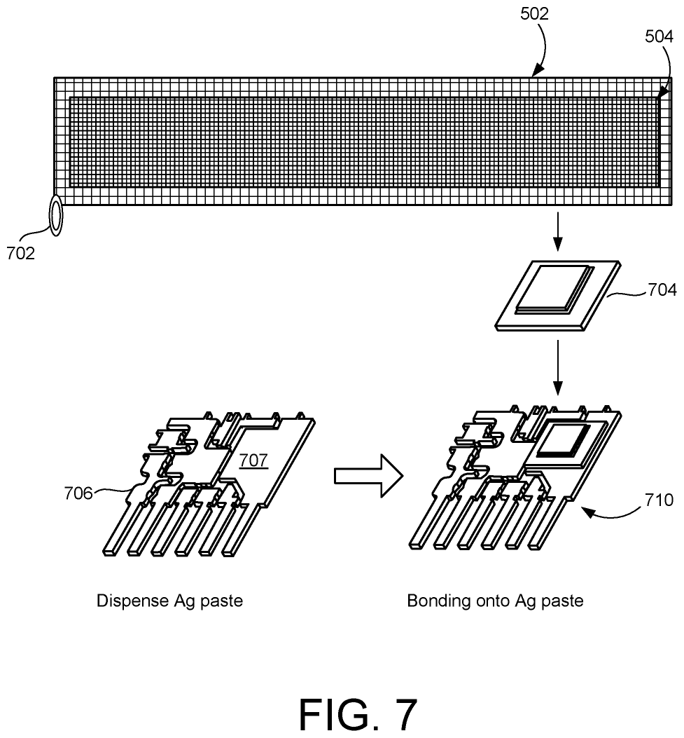

FIG. 7 illustrates further example processes for constructing the implementation of FIG. 2, which continue the example of FIGS. 5 and 6. Specifically, as shown, a dicing saw 702 may be used to singulate individual combinations 704 of IGBT/heatsinks.

Meanwhile, a leadframe 706 may have Ag paste 708 dispensed thereon, so that bonding may occur to obtain a resulting configuration 710 that corresponds to the example of FIG. 2. For example, the Ag paste 708 may be dispensed onto a bond pad, or die attach pad (DAP) 707, of the leadframe 706 that might normally be used to attach the individual IGBT 504 directly to the leadframe.

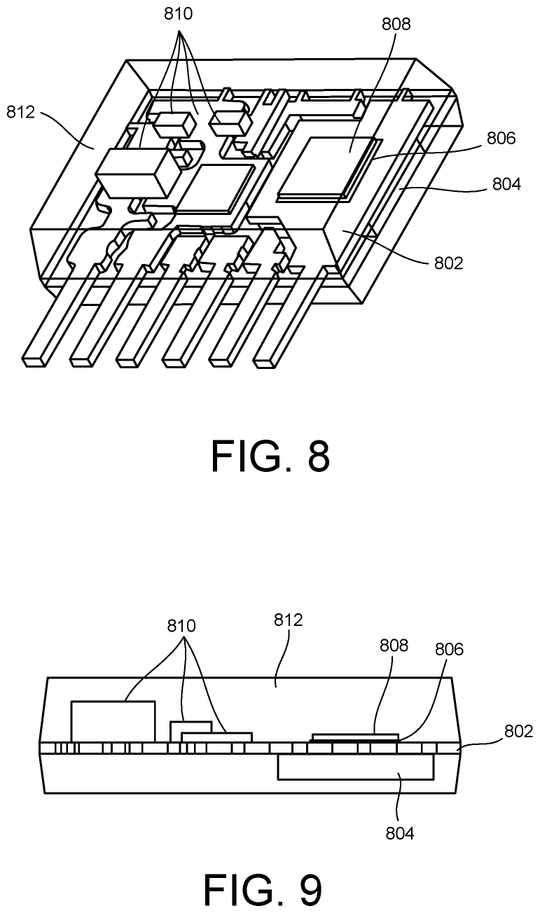

FIG. 8 is a side angle view of a second example implementation of the package of FIG. 1, with a heatsink mounted to an opposite side of a leadframe as a semiconductor device. FIG. 9 is a cross section view of the example of FIG. 8.

In FIGS. 8 and 9, a leadframe 802 is illustrated as having a heatsink 804 bonded thereon, on a surface that opposes a surface of the leadframe 802 on which bonding material 806 attaches semiconductor device 808, and on which various other semiconductor devices 810 are mounted, as well. As also shown, molding 812 encapsulates the leadframe 802, heatsink 804, and the various semiconductor devices 808, 810. Thus, FIGS. 8 and 9 illustrate a more detailed example implementation of FIG. 1, which includes the heatsink 104, but not the heatsink 106.

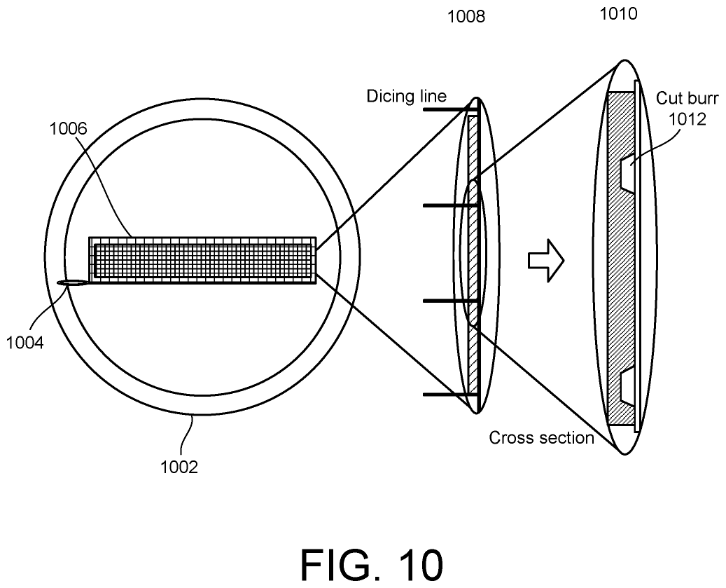

FIG. 10 illustrates an example process for heatsink dicing to obtain a heatsink for use in the example of FIGS. 8 and 9. As shown, a dicing sheet 1002 may include cut lines 1006 that are cut by a dicing saw 1004. As shown in exploded views 1008 and 1010, an example implementation of heat sink dicing for obtaining the heat sink 104/106 is illustrated. In FIG. 10, the cut burr 1012 generated during dicing occurs on the dicing sheet 1002 side. In some implementations, when bonding between a semiconductor device (e.g., IGBT device) and a leadframe, it is possible to use a surface without cut burrs.

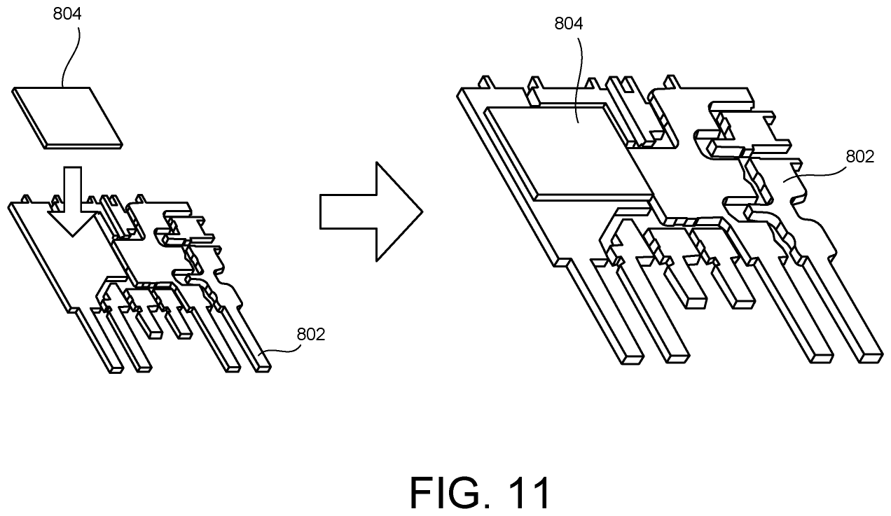

FIG. 11 illustrates a process for welding a heatsink obtained from the process of FIG. 10 to a leadframe to obtain the example of FIGS. 8 and 9. As shown, the heatsink 804 of FIG. 8 may be welded to the leadframe 802, using, e.g., ultrasonic, laser, or resistance welding. As described, Ag paste may also be used.

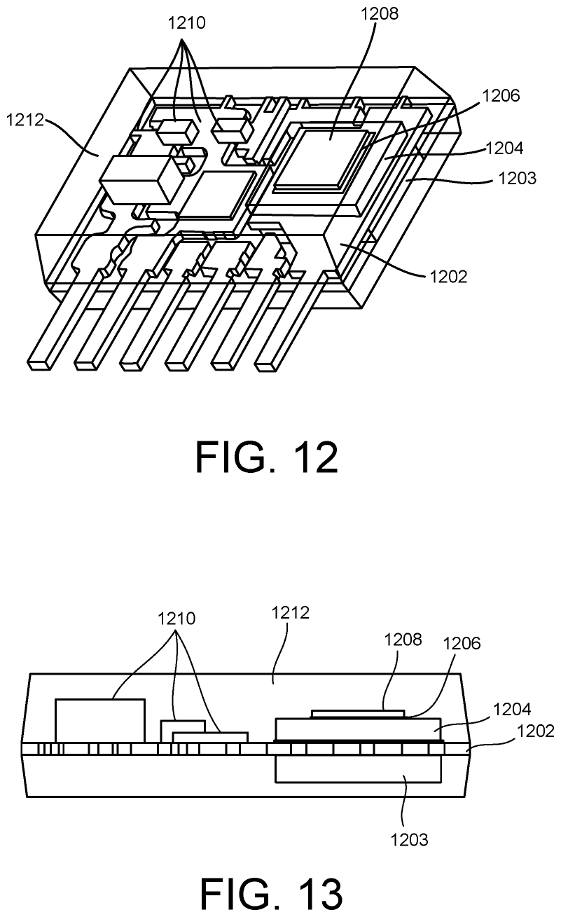

FIG. 12 is a side angle view of a third example implementation of the package of FIG. 1, with heatsinks mounted both between a semiconductor device and a leadframe, and to an opposite side of the leadframe. FIG. 13 is a cross section view of the example of FIG. 12.

As shown in FIGS. 12 and 13, a leadframe 1202 is illustrated as having a heatsink 1203 bonded thereon, on a surface that opposes a surface of the leadframe 1202 on which a heatsink 1204 is mounted. As further illustrated, bonding material 1206 attaches semiconductor device 1208 to the heatsink 1204. Various other semiconductor devices 1210 are mounted on the leadframe 1202, as well. As also shown, molding 1212 encapsulates the leadframe 1202, heatsinks 1203, 1204, and the various semiconductor devices 1208, 1210. Thus, FIGS. 12 and 13 illustrate a more detailed example implementation of FIG. 1, which includes instances of both the heatsink 104 and the heatsink 106.

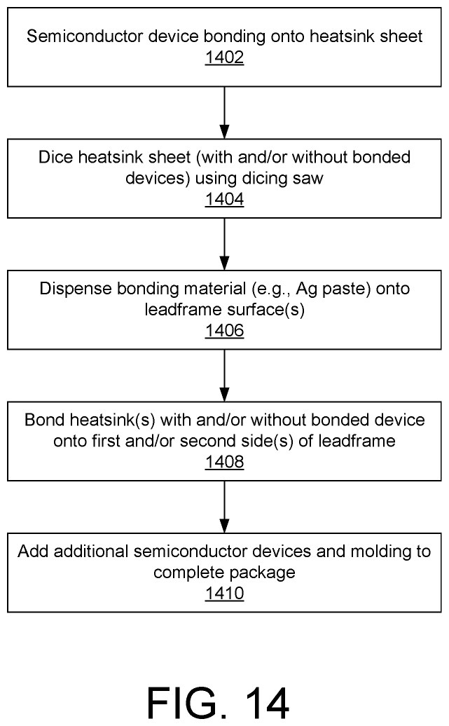

FIG. 14 is a flowchart illustrating an example process flow for manufacturing the example implementations of FIGS. 1-13. In the example of FIG. 14, a plurality of semiconductor devices (e.g., IGBT devices) may be bonded onto a heatsink sheet (1402), as illustrated and described above with respect to FIG. 5. For implementations which do not include a stacked heatsink/device configuration, operation 1402 may be omitted.

The heatsink sheet (either with or without semiconductor devices bonded thereon) may then be diced into individual heatsinks, e.g., using a dicing saw or other suitable dicing tool (1404). Example dicing processes are illustrated and described above, with respect to FIGS. 7 and 10.

A leadframe may then have a bonding material dispensed thereon (1406), to receive one of the individual heatsinks. For example Ag paste or other suitable solder material may be dispensed onto a die attach pad or other suitable surface of the leadframe, as illustrated and described in FIG. 6. Bonding material may be dispensed onto multiple portions of the leadframe, e.g., on each side thereof, in order to receive multiple heatsinks, as shown in FIGS. 1, 12, and 13.

Thus, one or more heatsinks may be bonded, with or without a semiconductor device bonded thereon, onto one or more surfaces of the leadframe (1408). In other implementations, as referenced, the heatsinks may be bonded using various types of welding, or any other technique suitable for providing metallurgical bonding.

Finally in FIG. 14, remaining semiconductor devices may be added as well, and the entire assembly may be encapsulated in molding to finalize the semiconductor package (1410).

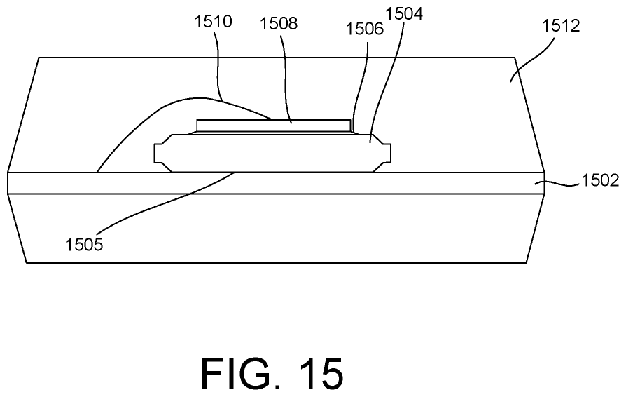

FIG. 15 is a cross section view of an example implementation of the semiconductor package of FIG. 1, showing relative thicknesses of various portions thereof. In FIG. 15, a leadframe 1502 is bonded to a heatsink 1504 by a bonding material 1505. Bonding material 1506 bonds a semiconductor device 1508 to the leadframe 1504. A contact wire 1510 connects the semiconductor device 1508 to another portion of the leadframe 1502 (e.g., to another device mounted thereon), and a molding 1512 encapsulates the entire assembly to define the finished semiconductor package.

In FIG. 15, by way of non-limiting example, the leadframe 1502 may have a thickness in a range of 0.25 to to 2.5 mm or more, e.g., 0.5 mm. The heatsink 1504 may have a thickness in a range of 0.5-1.25 mm, e.g., 0.8 mm. Bonding material 1505, such as Ag paste, may have a thickness of, e.g., 0.01-0.03 mm, e.g., 0.02 mm. The bonding material 1506 may have a thickness of, e.g., 0.04-0.08 mm, e.g., 0.06 mm. The contact wire 1510 may have a vertical clearance from the semiconductor device 1508 of at least 0.3 mm, e.g., 0.46 mm, while having a clearance from an upper surface of the molding 1512 of at least 0.5 mm, so that a distance from the upper surface of the molding to the semiconductor device 1508 may be at least 0.8 mm, e.g., 1.3 mm. The semiconductor device width will depend on the type of device used, but may be, e.g., 3.4 mm in a specific example of some IGBT devices. A width of the heatsink 1504 may depend on, e.g., may be larger than (e.g., 5.25 mm), the width of the semiconductor device 1508, and, as with the heatsink thickness, may be chosen to obtain a desired thermal transient response as described herein. A width of the entire package of FIG. 15 may depend on various factors and use case scenarios, but inclusion of the heatsink 1504 as described herein enables the maintaining of an overall small footprint of the device, e.g., less than 13 mm, or 11.8 mm in a specific example.

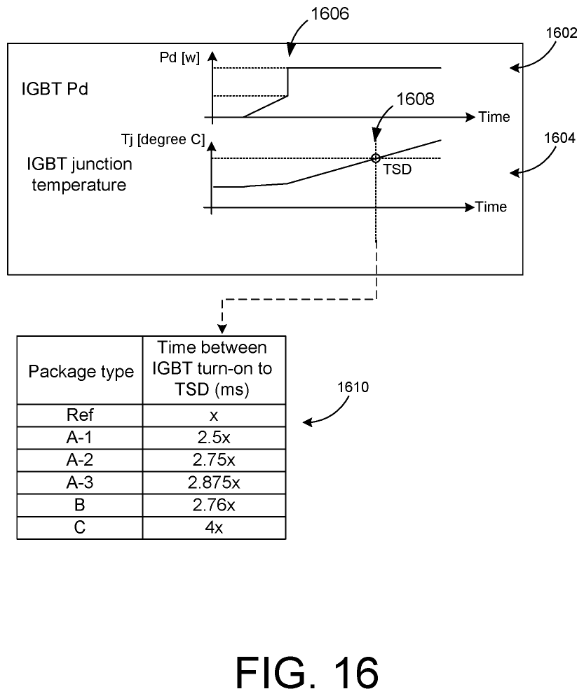

FIG. 16 illustrates graphs 1602, 1604 demonstrating a time until thermal shutdown of an example semiconductor device. More specifically, the graph 1602 illustrates a power curve for an IGBT device (which may be, e.g., in the tens or hundreds of Watts), including a high power (high temperature) event 1606 (which may occur, e.g., in a range of 50-60 W). Graph 1604 illustrates a corresponding IGBT junction temperature, including a point 1608 at which a temperature pre-defined for thermal shutdown is reached (which may occur, e.g., in a range of 180-220 C, e.g., 200 C).

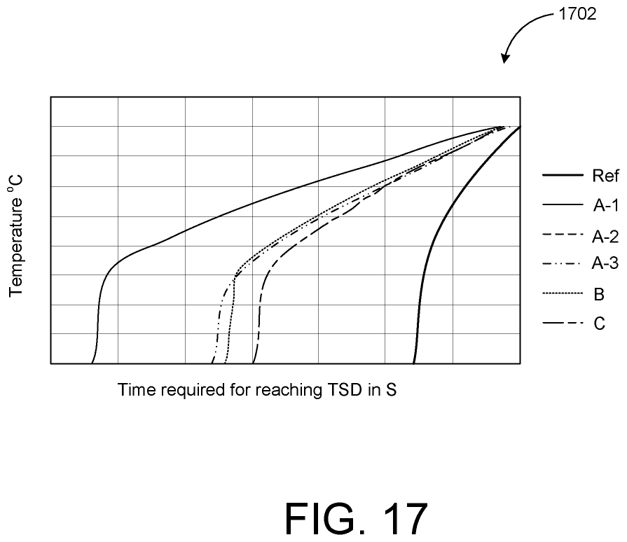

Further in FIG. 16, a table 1610 illustrates corresponding thermal response characteristics of various example implementations corresponding to the examples of FIGS. 1-15. In the table 1610, and in the remainder of FIGS. 17-20, the example implementation of FIGS. 2, 3 (with a stacked heatsink/device configuration) is referred to as type “A”, the example implementation of FIGS. 8, 9 (with a heatsink mounted to an opposing leadframe surface relative to a semiconductor device(s)) is referred to as type “B”, and the example implementation of FIGS. 12, 13 (with both a stacked heatsink/device configuration and a heatsink mounted to an opposing leadframe surface) is referred to as type “C”.

Further, as referenced above, different types of bonding materials and methods may have different thermal response characteristics. To illustrate related examples, the table 1610 includes three different example bonding materials/methods for Type A implementations, referenced as Type A-1, A-2, A-3. For example, type A-1 may have a solder attachment for a semiconductor device and Ag paste for the heatsink; type A-2 may have a sinter Ag attachment for a semiconductor device and Ag paste for the heatsink; and type A-3 may have a sinter Ag attachment for a semiconductor device and sinter Ag for the heatsink. Type B may use solder for the semiconductor device and welding (solid phase joining) for the heatsink. Type C may use solder for the semiconductor device and welding (solid phase joining) for the heatsink opposite the semiconductor device, while using Ag paste for the heatsink between the leadframe and the semiconductor device.

Table 1610 also includes a reference value, representing a leadframe with no heatsink attached. Values in Table 1610 are shown as relative values, where the reference value “x” may be in a range, e.g., of 70-100 ms, e.g., 80 ms.

Assuming that each heatsink used is the same or similar proportions relative to a particular leadframe, table 1610 illustrates that a range of TSD times may be obtained, with Type C having the largest thermal mass and therefore having the longest time to TSD, as compared to a reference (Ref) value representing no heatsink being included. Table 1610 illustrates that design requirements, such as a minimum and/or maximum time to TSD, may be selected and configured for desired implementations.

FIG. 17 is a graph illustrating a time required for different example implementations to reach a thermal shutdown temperature. As shown, FIG. 17 illustrates times required for the various implementations of FIG. 16 to reach a TSD temperature, relative to the reference values. The time required may be in a range, for example of less than 0.5 s.

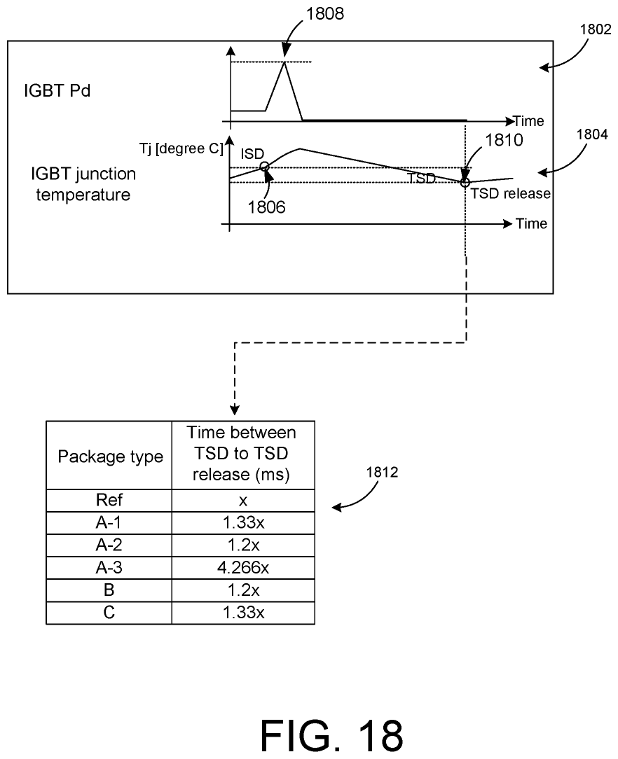

FIG. 18 illustrates graphs 1802, 1804 demonstrating a time until thermal release following the example thermal shutdowns of FIGS. 16 and 17. As in FIG. 16, a power curve of an IGBT is shown in graph 1802, while an IGBT junction temperature curve is shown in graph 1804.

As shown in FIG. 18, a TSD occurs at time 1806, which is followed by the reaching of a maximum temperature at time 1808. A time 1810 reflects a time of thermal release, i.e., a time between 1806 and 1808.

Table 1812 illustrates various example times until thermal release for the various implementations referenced in table 1610 of FIG. 6. Thermal release times may be on the order of tens of milliseconds, for example. As shown, a wide range of TSD release times are available, with notable differences between the Types A-1, A-2, and A-3.

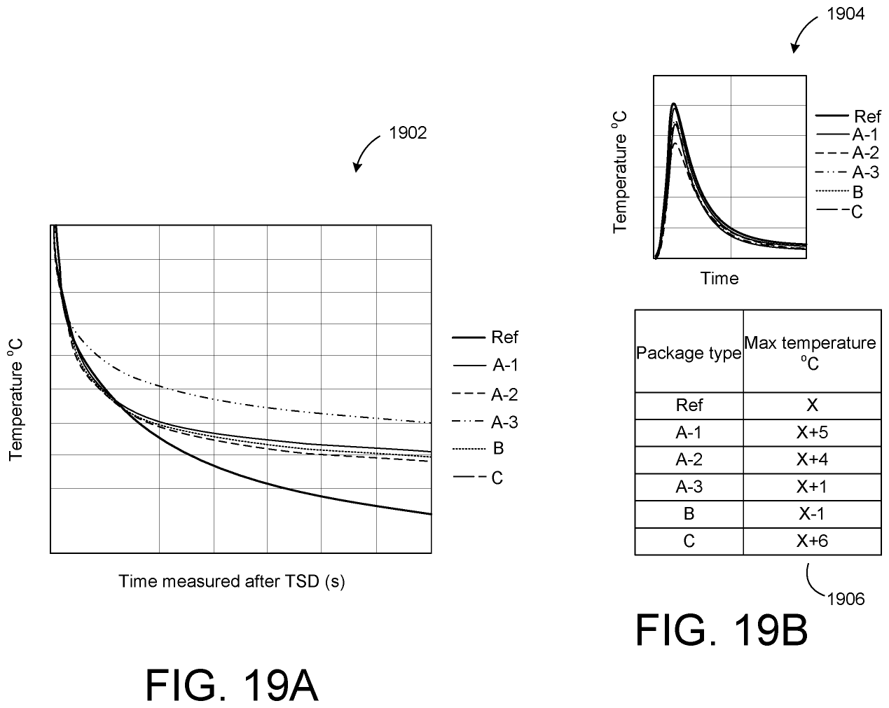

FIG. 19A is a graph 1902 illustrating a time required for different example implementations to reach thermal release. FIG. 19B illustrates a graph 1904 representing a maximum temperature reached for each implementation, as represented in table 1906. Maximum temperature may be higher than a temperature for thermal shutdown by tens of degrees.

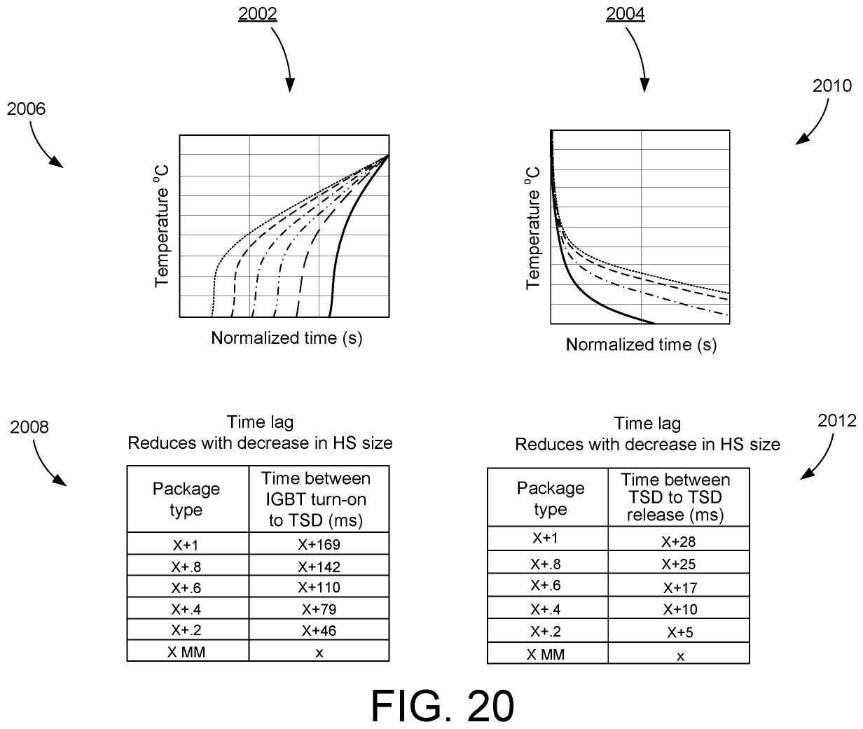

FIG. 20 illustrates graphs demonstrating example configuration options for optimizing a transient thermal response of the semiconductor package of FIG. 1. In FIG. 20, the configuration of Type B and FIGS. 8, 9 is illustrated, but with different sizes of heatsinks used.

Thus, thermal shutdown characteristics of such implementations are illustrated (2002), as well as corresponding thermal release characteristics (2004). For example, graph 2006 illustrates a normalized time exhibited by the different implementations to reach a TSD temperature, as also captured in corresponding table 2008.

Meanwhile, a graph 2010 illustrates a normalized time to thermal release for each implementation. A table 2012 captured the corresponding time values. As thus demonstrated by FIG. 20, decreases in heatsink size generally correspond with an increased time to thermal shutdown, as well as a corresponding increased time until thermal release.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device package, comprising:
a leadframe;
a heatsink bonded to the leadframe;
a semiconductor device mounted using the leadframe and positioned such that heat generated by the semiconductor device is conducted by the heatsink; and
molding that encapsulates the leadframe, the heatsink, and the semiconductor device.

2. The semiconductor device package of claim 1, wherein the heatsink is bonded between the semiconductor device and the leadframe.

3. The semiconductor device package of claim 1, wherein the semiconductor device is mounted on a first surface of the leadframe, and the heatsink is bonded to a second, opposed surface of the leadframe.

4. The semiconductor device package of claim 1, wherein the heatsink is bonded to the leadframe using solder.

5. The semiconductor device package of claim 1, wherein the heatsink is welded to the leadframe.

6. The semiconductor device package of claim 1, wherein the heatsink is completely encapsulated by the molding.

7. The semiconductor device package of claim 1, wherein the heatsink includes copper.

8. The semiconductor device package of claim 1, further comprising a second heatsink metallurgically bonded to the heatsink.

9. The semiconductor device package of claim 1, wherein dimensions of the heatsink define a transient thermal response of the semiconductor device including a time to thermal shutdown and a time to thermal release following the thermal shutdown.

10. A semiconductor device package, comprising:
a leadframe having a substantially flat leadframe surface;
a heatsink having a substantially flat heatsink surface that is bonded to the substantially flat leadframe surface; and
a semiconductor device mounted using the leadframe and positioned such that heat generated by the semiconductor device is conducted by the heatsink.

11. The semiconductor device package of claim 10, further comprising:
molding that encapsulates the leadframe, the heatsink, and the semiconductor device.

12. The semiconductor device package of claim 10, wherein the heatsink is bonded between the semiconductor device and the leadframe.

13. The semiconductor device package of claim 10, wherein the semiconductor device is mounted on a first surface of the leadframe, and the heatsink is bonded to a second, opposed surface of the leadframe.

14. A method of manufacturing a semiconductor device package, comprising:
bonding a heatsink onto a leadframe;
mounting a semiconductor device using the leadframe; and
encapsulating the leadframe, the semiconductor device, and the heatsink within a molding.

15. The method of claim 14, wherein bonding the heatsink comprises:
bonding the heatsink between the semiconductor device and the leadframe.

16. The method of claim 14, wherein the semiconductor device is mounted on a first surface of the leadframe, and wherein bonding the heatsink comprises:
bonding the heatsink to a second, opposed surface of the leadframe.

17. The method of claim 14, wherein the heatsink has a substantially flat surface, and bonding the heatsink comprises:
bonding the substantially flat surface of the heatsink to a substantially flat surface of the leadframe.

18. The method of claim 14, comprising:
dicing the heatsink from a sheet of heatsink material.

19. The method of claim 14, comprising:
forming the heatsink with dimensions to achieve a pre-configured transient thermal response of the semiconductor device with respect to a thermal shutdown of the semiconductor device.

20. The method of claim 19, wherein the thermal transience response includes a time to thermal shutdown and a time to thermal release following the thermal shutdown.
